(19) United States
(12) Patent Application Publication
(10) Pub. No.: US 2021/0249548 A1
(43) Pub. Date: Aug. 12, 2021

(54) REPAIR TAPE AND METHOD OF REPAIRING A DAMAGED BACKSHEET OF SOLAR CELL MODULE USING THE SAME

(71) Applicant: DUPONT ELECTRONICS, INC., Wlmington, DE (US)

(72) Inventor: Yichen Hu, Shanghai (CN)

(21) Appl. No.: 17/121,557

(22) Filed: Dec. 14, 2020

(30) Foreign Application Priority Data
Jan. 10, 2020 (CN) 202010024551.7
Jan. 10, 2020 (CN) 202020046775.3

(51) Int. Cl. H01L 31/049; H02S 99/00; H01L 31/048

(52) U.S. Cl. CPC H01L 31/049; H01L 31/0481; H02S 99/00

(57) ABSTRACT

A repair tape for solar cell backsheets, comprising a rubber adhesive layer; a substrate film; and a protective layer, laminated in this order, wherein thickness of the rubber adhesive layer is more than 200 μm.

### BACKGROUND OF THE INVENTION

### Field of the Disclosure

The present invention relates to repair tape for solar cell backsheet and a method for repairing a damaged backsheet of solar cell module.

### Description of the Related Art

Solar cells are used to produce electrical energy from sunlight, offering a more environmentally friendly alternative to traditional methods of electricity generation.

These solar cells are built from various semiconductor systems which must be protected from environmental effects such as moisture, oxygen, and UV light. The cells are usually jacketed on both sides by protective layers of glass and/or plastic films forming a multilayer structure known as a photovoltaic (PV) module. On the rear side of the module, film composite called backsheet is typically placed.

The backsheet plays a critical role in protecting solar modules from harsh, varying environmental conditions over panel lifetimes. However, various types of backsheet related defects were found during the field lifetime, such as crack, efflorescence, yellowing and scratch. These failures can lead to catastrophic breakdown of panels, significant power degradation and severe safety hazards.

To address the damage of backsheet, repair tapes and repair materials are proposed in CN110055008, CN109517534, CN108165197, CN107841259A, CN107841259, CN205680696U and CN202482248U.

### SUMMARY

In a first aspect, the present invention is a repair tape for solar cell backsheets, comprising a rubber adhesive layer; a substrate film; and a protective layer, laminated in this order, wherein thickness of the rubber adhesive layer is more than 200 μm.

In a second aspect, the present invention is a method of repairing a damaged backsheet of solar cell module, comprising the steps of preparing a repair tape, wherein the repair tape comprises a rubber adhesive layer; a substrate film; and a protective layer, laminated in this order, wherein thickness of the rubber adhesive layer is more than 200 μm, and wherein the repair tape is substantively the same size in width as the backsheet; placing the repair tape onto the damaged backsheet in a way that the rubber adhesive layer is facing toward the damaged backsheet; and adhering the repair tape to the backsheet.

In a third aspect, the present invention is a repair equipment for repairing a damaged backsheet of solar cell module, comprising: a base board, on which the solar cell module with the damaged backsheet is placed in a way the damaged backsheet faces upward; and a roller attached to the base board, wherein the roller is movable in the vertical direction to press a repair tape onto the damaged backsheet and wherein the roller is movable in the horizontal direction to press the repair tape from one end of the repair tape to the other end of the repair tape.

The foregoing general description and the following detailed description are exemplary and explanatory only and are not restrictive of the invention, as defined in the appended claims.

### BRIEF DESCRIPTION OF THE DRAWINGS

FIG. 1 shows a cross sectional view of a repair tape for solar cell backsheet.

FIGS. 2 through 8 illustrates a process of repairing a damaged backsheet of solar cell module. FIG. 2 is a back view of damaged solar cell module, in which cracks are formed in the backsheet. FIG. 3 shows a step of placing a repair tape onto the damaged backsheet. FIG. 4 shows a step of making a hole in the repair tape corresponding to the junction box. FIG. 5 shows a step of placing a nip roller at the front end of the repair tape.

FIG. 6 shows a step of pulling the repair tape toward the front end over the nip roller. FIG. 7 shows a step of moving the nip roller toward the rear end of the backsheet. FIG. 8 illustrate the entire repair tape is adhered to the damaged backsheet.

### DETAILED DESCRIPTION

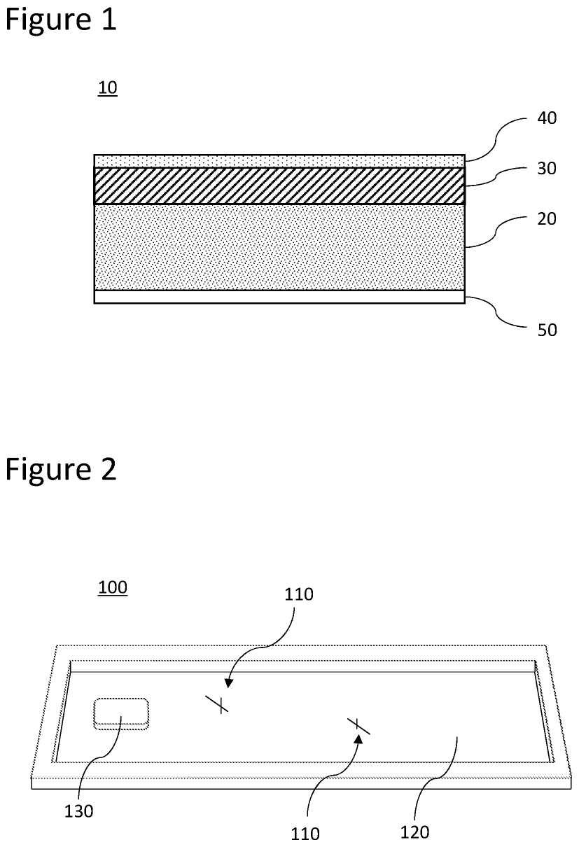

In a first aspect, a repair tape (10) for solar cell backsheet comprises a rubber adhesive layer (20); a substrate film (30); and a protective layer (40), laminated in this order, wherein thickness of the rubber adhesive layer is more than 200 μm, as illustrated in FIG. 1. A release film (50) is placed on the outer surface of the rubber adhesive layer (20) in an embodiment.

### Substrate Film

Substrate films (30) may be selected from a wide range of polymers. In one embodiment, the polymeric substrate film is a polymeric film comprising a polyester, a polyethylene, a polypropylene, a polyethylene terephthalate, a polyethylene naphthalate, a polyvinyl chloride, a polyamide or a polyimide. In one embodiment, the polymeric film comprises a thermoplastic polymer, which may be desirable for its ability to withstand higher processing temperatures. In an embodiment, the substrate film is a polyester film. A polyester for the substrate film is selected from polyethylene terephthalate, polyethylene naphthalate and a co-extrudate of polyethylene terephthalate/polyethylene naphthalate in an embodiment. A polyester for the substrate film is polyethylene terephthalate in another embodiment.

Fillers may also be included in the substrate film, where their presence may improve the physical properties of the substrate film, for example, higher modulus and tensile strength. They may also improve adhesion of the protective layer to the polymeric substrate film. One exemplary filler is barium sulfate, although others may also be used.

The substrate film comprises about 90-100 weight % of polymer in an embodiment, and about 95-100 weight % of polymer in another embodiment based on the total weight of the substrate film.

Thickness of the substrate film is about 50 μm to about 200 μm in an embodiment, and about 100 μm to about 150 μm in another embodiment.

Commercially available films such as Yuxing CY11, CY11G48, CY11GU, CY25, CY25R, CY25R-11S, CR25RG48, CR25RG60, CY28, CY25T, Dongcai D269, D269-UV, DF6027, DS10C-UV, DS10, DS11, DS10C can be used for the substrate film.

The substrate film may consist of multiple polymeric films in an embodiment.

### Protective Layers

Protective layer (40) is typically adhered to a first side of the substrate film. There are no specific restrictions on the type of the protective layer. A fluoropolymer is used in an embodiment.

The fluoropolymer can be any fluoropolymer known in the art, including homopolymers of fluorinated monomers, copolymers of fluorinated monomers, or copolymers of a fluorinated monomer and a non-fluorinated monomer, as long as monomer units derived from the fluorinated monomer in the copolymer account for more than about 20 percent by weight based on the overall weight of the copolymer, or from about 40 to about 99 percent by weight.

The fluoropolymer may, for example, be comprised of polyvinyl fluoride (PVF), polyvinylidene fluoride (PVDF), polytetrafluoroethylene (PTFE), hexafluoropropylene (HFP), polychlorotrifluoroethylene (PCTFE), ethylene-tetrafluoroethylene copolymer (ETFE), fluoroethylene-alkyl vinyl ether copolymer (FEVE), tetrafluoroethylene-hexafluoropropylene copolymer (FEP), tetrafluoroethylene/hexafluoropropylene/vinylidene fluoride terpolymer (THV), copolymers and terpolymers comprising polyvinyl fluoride and polytetrafluoroethylene, and the like. The fluoropolymer is a polyvinyl fluoride (PVF) in an embodiment.

In one embodiment, the protective layer may include additives. Additives may include, for example, light stabilizer, UV stabilizers, thermal stabilizers, anti-hydrolytic agents, light reflection agents, pigments, titanium dioxide, dyes, and slip agents. Suitable fluoropolymer films are commercially available. For example, PVF film is sold by DuPont under the trade name Tedlar®.

The protective layer includes about 90-100 weight % of fluoropolymer in an embodiment, and about 95-100 weight % of fluoropolymer in another embodiment based on the total weight of the protective layer.

Thickness of the protective layer is about 5 μm to about 50 μm in an embodiment, and about 15 μm to about 35 μm in another embodiment.

Commercially available sheets such as DuPont Tedlar® PV2001, PV2025, PV2025A, PV2002, or PV3001 can be used for the protective layer.

The protective layer may consist of multiple fluoropolymer films in an embodiment.

### Rubber Adhesive Layer

Rubber adhesive layer (20) is typically adhered to a second side of the substrate film. The second side is the opposite side of the first side, on which the rubber adhesive layer is formed. There are no specific restrictions on the type of the rubber adhesive layer. Rubber adhesive includes, but not limited to, butyl rubber, silicone rubber, fluorocarbon rubber, EPDM rubber, urethane rubber and natural rubber. A butyl rubber layer is used in an embodiment.

The butyl rubber is an isobutene-isoprene copolymer, has the structure of Formula (1), which is abbreviated as IIR. The butyl rubber can be produced by copolymerizing isobutene and a small amount of isoprene with a Friedel-Crafts catalyst in a methyl chloride solvent at a low temperature of around −95° C. The butyl rubber may be substituted by a halogen in an embodiment.

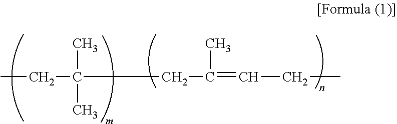

In Formula (1), m and n each represent a positive integer.

Various known additives may be added to the rubber adhesive to satisfy various requirements of the repair tape. Suitable additives may include, for example, light stabilizer, UV stabilizers, thermal stabilizers, anti-hydrolytic agents, light reflection agents, pigments, titanium dioxide, dyes, and slip agents. There are no specific restrictions to the content of the additives, as long as the additives do not produce an adverse impact on the final adhesion properties of the repair tape.

The rubber adhesive layer includes about 90-100 weight % of rubber in an embodiment, and about 95-100 weight % of rubber in another embodiment based on the total weight of the rubber adhesive layer.

Thickness of the rubber adhesive layer is about 200 μm to about 600 μm in an embodiment, about 300 μm to about 600 μm in another embodiment, and about 350 μm to about 600 μm in another embodiment. Superior adhesion can be formed by using a thick rubber adhesive layer. Specific technical advantages of using thick rubber adhesive layer are shown in the experimental section below.

Commercially available rubbers such as ExxonMobil Exxon™ butyl rubber 065, 365, 068, 268, Lanxess X Butyl™ BB 2030, BB 2040, RB 100, RB 301, RB 402, JSR butyl 065, 268, 365, 1066, 2244, 2255, Sibur BK-1675N, Yanshan IIR1751, Cenway IIR 532, IIR 552 or Heyun IIR 1650 can be used for the rubber adhesive layer.

The rubber adhesive layer may consist of multiple rubber adhesive layers in an embodiment.

### Release Films

Release film (50) is placed on the outer surface of the rubber adhesive layer (20). The release film is typically removed prior to the use of the repair tape. The release film requires a moderate (or reasonable) releasability (peelability) from the rubber adhesive layer and moderate (or reasonable) adhesion to the rubber adhesive layer.

Type of the release film is not particularly limited. A fluorine-containing polymeric film is used in an embodiment. The fluorine-containing polymeric film has excellent heat resistance, releasability, and stain resistance. A release film containing a cyclic olefin polymer is used in another embodiment.

Commercially available films such as Chemours™ Teflon® FEP film, 0.5-20 mm; Daikin Neoflon NF-0012, NF-0025, NF-0050, NF-0100, NF-0125, NF-0250, NF-0500, NF-0750, NF-1000, NF-1500, NF-2400, 12-2400 μm; 3M™ Dyneon FEP film, Chemours™ Tefzel™ FEP film; AGC Fluon® ETFE film, 12-250 μm; Daikin Neoflon EP-521, EP-541, EP-610, EP-620, EP-700; PET film; OPP film can be used for the release film.

### Repair Tape

The repair tape is used to repair or support the backsheet for a photovoltaic module, providing long-term mechanical, electrical and other barrier protection to the sensitive solar cells within the module. In one embodiment, the repair tape has an oxygen transmission rate of less than 4.0 cc/m²-day, or less than 2.0 cc/m²-day, or less than 1.0 cc/m²-day. In another embodiment, the repair tape has a water vapor transmittance rate of less than 4.0 cc/m²-day, or less than 2.0 cc/m²-day, or less than 1.0 cc/m²-day

### Photovoltaic (Solar Cell) Module

In an exemplary embodiment, a glass sheet, a front encapsulant layer, a solar cell layer, a back encapsulant layer and a backsheet are laminated together with heat and pressure and under vacuum to remove air. Preferably, the glass sheet has been washed and dried.

If desired, the edges of the photovoltaic module may be sealed to reduce moisture and air intrusion by any means known within the art. Such moisture and air intrusion may degrade the efficiency and lifetime of the photovoltaic module.

### Repair Process

A repair process is described below, however the repairing process is not limited to a specific embodiment. In an embodiment, the repair tape, which is substantively the same in size as the backsheet, is laminated onto the backsheet. In an embodiment, the repair tape is cut into a suitable size to cover the damaged area of the backsheet.

FIG. 2 is a back view of a damaged solar cell module. The damaged module (100) contains cracks (110) on the backsheet (120). Typically, a junction box (130) is placed on the back side of the module. Cables or codes are typically connected to the junction box (not shown in the figures).

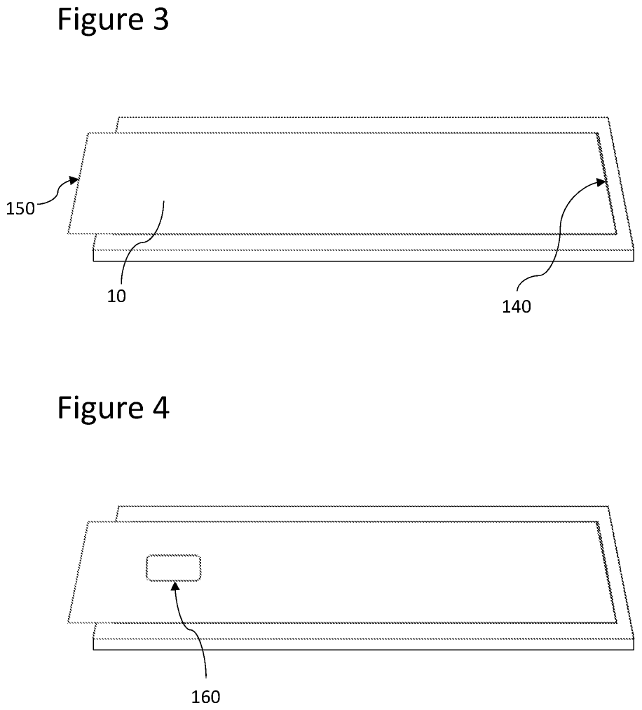

A repair tape (10) is placed on the backsheet as illustrated in FIG. 3. The repair tape is placed in a way the rubber adhesive layer optionally covered with the release film faces the backsheet and the protective layer faces the outer atmosphere.

The repair tape has the substantively same width as the damaged backsheet in an embodiment. More specifically, the repair tape has a width of about 90 to 100% of the damaged backsheet in an embodiment and about 95 to 100% of the damaged backsheet in an embodiment.

The repair tape can be a slightly wider than that of the damaged backsheet in an embodiment so that the repair tape can seal the edge with the surplus. For the same reason, the front end (140) of the repair tape can be slightly longer than the actual length of the backsheet. Trapped air between the repair tape (10) and the backsheet (120) can be removed by a roller or a squeegee.

When the repair tape has a release film attached on the outer surface of the rubber adhesive layer, the release film at the front end is partially peeled off to expose part of the rubber adhesive layer (not shown in the figure). The front end of the repair tape (10) is fixed by adhering the rubber adhesive layer onto the backsheet. The partially separated release film may then be removed completely by pulling its separated portion toward the rear end (150) of the repair tape. The adhesion can be conducted by use of a squeegee or a blade in an embodiment.

The area of the repair tape corresponding to the junction box is opened to form a hole by a proper tool such as cutter and grip knife as in FIG. 4. In an embodiment, the hole (160) can be made in advance to the placement of the repair tape onto the backsheet. The size of the hole is just the same size as the junction box in an embodiment. For avoiding an adjustment error, the hole may be a slightly larger than the actual size of the junction box.

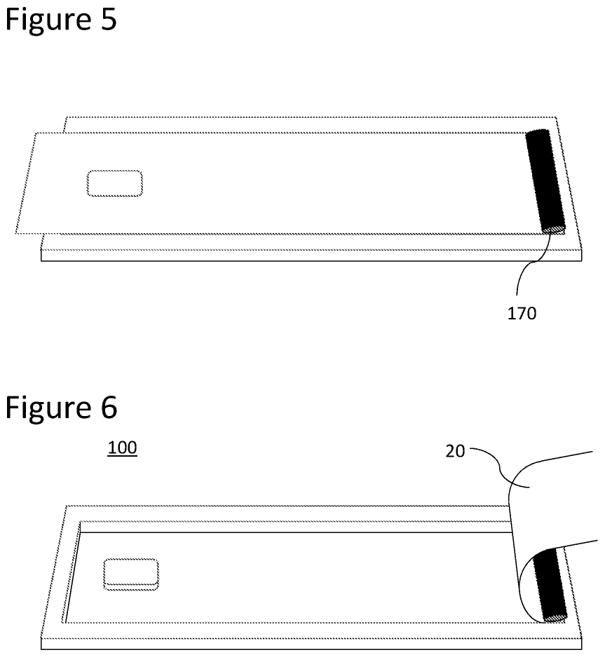

Alternatively, a roller (170) is placed at the front end of the repair tape, in which the repair tape is adhered to the backsheet in the previous step (FIG. 5). The roller is movable in the vertical direction to press the repair tape onto the damaged backsheet. In an embodiment, the adhesion of the repair tape in the following step is manually conducted by use of a squeegee or a blade without a roller. However, the productivity usually becomes higher by use of a roller.

The repair tape is pulled toward the front end over a roller as illustrated in FIG. 6. The roller is a nip roller made of rubber in an embodiment. When the repair tape has the release film, the release film is peeled off and the rubber adhesive layer (20) is exposed. As the front end of the repair tape is adhered in the previous step and fixed by the roller when the release film is peeled off.

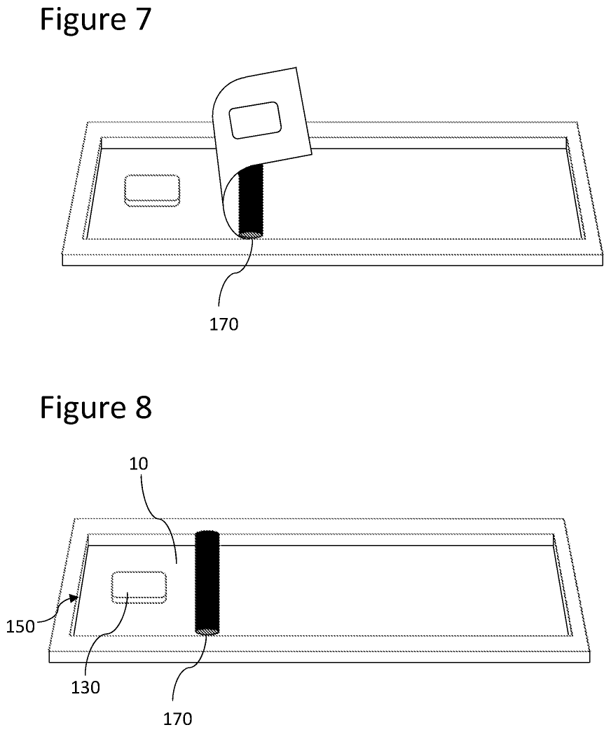

The roller (170) is moved in the horizontal direction toward the rear end of the repair tape (FIG. 7). Bubble inclusion can be prevented by use of a roller with a proper size and a proper weight. A proper pressure can be put onto the repair tale by the weight of the roller and sufficient adhesion between the rubber adhesive layer and the damaged backsheet can be achieved. The roller is placed on a guide rail along the long side of the module so that the roller moves straight along with the module in an embodiment. The guide rail provides a certain warp angle and certain pressure to prevent bubbles and creases during the adhesion process.

The roller (170) is stopped in a proper distance before reaching the junction box (130) and the rear end (150) of the repair tape is manually adhered to the backsheet (FIG. 8). The roller can be moved back to the original position. Cables and codes connected to the junction box (130) are pulled out through the hole (160) made in the repair tape. When the rear end (150) of the repair tape is longer than the actual size of the module, the repair tape may be cut by a proper tool such as cutter and grip knife.

The adhesion of the repair tape, especially around the rear end of the repair tape is made certain by use of a squeegee or a blade without a roller in an embodiment.

### Repair Equipment

In an embodiment, a repair equipment for repairing a damaged backsheet comprises a base board (not shown) and a roller (170).

The base board is a flat board or foundation, which is substantively the same or larger than the size of the solar cell module to be repaired. The solar cell module with the damaged backsheet is placed in a way the damaged backsheet faces upward.

The repair equipment has a roller attached to the base board. The attachment style is not limited. In an embodiment, the repair equipment has a set of guide rail placed along with the longer sides of the solar cell module to be repaired and a movable member on the guide rail. The movable member moves on the guide rail in a horizontal direction from one end to the other end. The roller is attached to the base board by use of a metal bar and the movable member in an embodiment. The roller is movable in a direction perpendicular to the base board, i.e. up and down along the vertical direction. In an embodiment, the roller is moved vertically by using the metal bar as leverage.

When the roller is placed in the “up” position, there is space between the solar cell module and the roller. The repair tape is inserted while the roller is in the upper position in an embodiment. The roller is placed outside of the solar cell module when the repair tape is placed onto the damaged solar cell module in another embodiment.

When the roller is placed in the “down” position (cf. FIGS. 5-8), a proper pressure is imposed onto the repair tape so that the repair tape adheres to the damaged backsheet. The roller is moved in the horizontal direction to press the repair tape from one end of the repair tape (i.e. the front end) to the other end of the repair tape (i.e. the rear end or before reaching the junction box) as illustrated in FIGS. 6-7.

While the presently disclosed invention has been illustrated and described with reference to preferred embodiments thereof, it will be appreciated by those skilled in the art that various changes and modifications can be made without departing from the scope of the present invention as defined in the appended claims.

The repair process and repair equipment described above can be used for other repair tapes. Namely, an aspect of the repair process is described as follows.

A method of repairing a damaged backsheet of solar cell module, comprising the steps of:
preparing a repair tape, wherein the repair tape comprises a release film, an adhesive layer and a protective layer, laminated in this order, wherein the repair tape is substantively the same size in width as the backsheet;

placing the repair tape onto the damaged backsheet in a way the release film faces the damaged backsheet;

peeling off a one end (front end) of the release film to partly expose the adhesive layer;

adhering the partly exposed adhesive layer to the damaged backsheet;

placing a roller onto the adhered repair tape at the one end;

peeling off the rest of the release film; and

adhering the unadhered adhesive layer to the damaged backsheet by moving the roller toward the other end (rear end).

Some modifications can be made into the process. For example, the release film can be peeled off while moving the roller toward the rear end. Such a modification is described as follows.

A method for repairing a damaged backsheet of solar cell module, comprising the steps of:

preparing a repair tape, wherein the repair tape comprises a release film, an adhesive layer and a protective layer, laminated in this order, wherein the repair tape is substantively the same size in width as the backsheet;

placing the repair tape onto the damaged backsheet in a way the release film faces the damaged backsheet;

peeling off a one end (front end) of the release film to partly expose the adhesive layer;

adhering the partly exposed adhesive layer to the damaged backsheet;

placing a roller onto the adhered repair tape at the one end;

adhering the unadhered adhesive layer to the damaged backsheet by moving the roller toward the other end (rear end) while peeling off the rest of the release film.

### Definitions

The following definitions are used herein to further define and describe the disclosure.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The terms “a” and “an” include the concepts of “at least one” and “one or more than one”.

Unless stated otherwise, all percentages, parts, ratios, etc., are by weight.

The terms “sheet”, “layer” and “film” are used in their broad sense interchangeably. A “backsheet” is a sheet, layer or film on the side of a photovoltaic module that faces away from a light source, and is generally opaque.

“Encapsulant” means material used to encase the fragile voltage-generating solar cell layer to protect it from environmental or physical damage and hold it in place in a photovoltaic module. Encapsulant layers are conventionally positioned between the solar cell layer and the incident front sheet layer, and between the solar cell layer and the backsheet backing layer. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to frontsheets, backsheets, other rigid polymeric sheets and solar cell surfaces, and long term weatherability.

The term “copolymer” is used herein to refer to polymers containing copolymerized units of two different monomers (a dipolymer), or more than two different monomers.

### EXAMPLES

The concepts described herein will be further described in the following examples, which do not limit the scope of the invention described in the claims.

Materials

The following materials were used in the following experiments.

Protective Layer: polyvinyl fluoride (PVF), 25 μm, DuPont Tedlar® PV2025A

Substrate Film: polyethylene terephthalate (PET), 125 μm, Yuxing CY11

Rubber Adhesive Layer: butyl rubber, 150-580 μm, Sibur BK-1675N

Release Film: Ranrui 25c PET film

### Examples 1-5 and Comparative Example 1

A laminate film having a construction of PVF/PET/rubber adhesive layer/release film was made. The lamination was conducted by extruding an adhesive material onto the PET film at the condition of 110-130° C. The thickness of the rubber adhesive layer was changed as shown in Table 1.

Adhesion strength was measured by Instron Universal Tester according to GB/T 31034-2014. Each example and comparative example were cut to provide 5 samples with a length of 150 mm and a width of 25 mm were tested at a speed of 100 mm/min.

TABLE 1

| | Protective | Substrate | Adhesive | Adhesion |
|---|---|---|---|---|
| | Layer | Film | Layer | strength (N/cm) |
| Comparative 1 | PVF | PET | Butyl rubber | 7.74 |
| | 25 μm | 125 μm | 150 μm | |
| Example 1 | PVF | PET | Butyl rubber | 14.80 |
| | 25 μm | 125 μm | 270 μm | |
| Example 2 | PVF | PET | Butyl rubber | 17.64 |
| | 25 μm | 125 μm | 370 μm | |
| Example 3 | PVF | PET | Butyl rubber | 21.92 |
| | 25 μm | 125 μm | 480 μm | |
| Example 4 | PVF | PET | Butyl rubber | 22.30 |
| | 25 μm | 125 μm | 520 μm | |
| Example 5 | PVF | PET | Butyl rubber | 26.38 |
| | 25 μm | 125 μm | 580 μm | |

As Table 1 shows, it was found that the adhesion of the repair tape sample becomes strengthened by a thicker rubber adhesive layer. Stronger adhesion typically contributes to long-term reliability of the repair tape. As solar cell modules are put in the field for decades, the long-term reliability is one of the critical requirements.

In the foregoing specification, the invention has been described with reference to specific embodiments. However, one of ordinary skill in the art appreciates that one or more modifications or one or more other changes can be made without departing from the scope of the invention as set forth in the claims below. Accordingly, the specification is to be regarded in an illustrative rather than a restrictive sense and any and all such modifications and other changes are intended to be included within the scope of invention.

What is claimed is:

1. A repair tape for solar cell backsheets, comprising:
a rubber adhesive layer;
a substrate film; and
a protective layer, laminated in this order,
wherein thickness of the rubber adhesive layer is more than 200 μm.

2. The repair tape according to claim 1, wherein the thickness of the rubber adhesive layer is 200 μm to 600 μm.

3. The repair tape according to claim 1, wherein the thickness of the rubber adhesive layer is 300 μm to 600 μm.

4. The repair tape according to claim 1, wherein the rubber adhesive layer comprises butyl rubber.

5. The repair tape according to claim 1, wherein thickness of the substrate film is 50 μm to 200 μm.

6. The repair tape according to claim 1, wherein the substrate film is a polyester film.

7. The repair tape according to claim 6, wherein the substrate film comprises a polyethylene terephthalate.

8. The repair tape according to claim 1, wherein thickness of the protective layer is 5 μm to 50 μm.

9. The repair tape according to claim 1, wherein the protective layer comprises fluoropolymer.

10. The repair tape according to claim 8, wherein the protective layer comprises polyvinyl fluoride.

11. The repair tape according to claim 1, further comprising a release film attached on the outer surface of the rubber adhesive layer.

12. A method for repairing a damaged backsheet of solar cell module, comprising the steps of:
preparing a repair tape, wherein the repair tape comprises a rubber adhesive layer, a substrate film, and a protective layer, laminated in this order, wherein thickness of the rubber adhesive layer is more than 200 μm, and wherein the repair tape is substantively the same size in width as the backsheet;
placing the repair tape onto the damaged backsheet in a way that the rubber adhesive layer is facing toward the damaged backsheet; and
adhering the repair tape to the backsheet.

13. A repair equipment for repairing a damaged backsheet of solar cell module, comprising:
a base board, on which the solar cell module with the damaged backsheet is placed in a way the damaged backsheet faces upward; and
a roller attached to the base board, wherein the roller is movable in the vertical direction to press a repair tape onto the damaged backsheet and wherein the roller is movable in the horizontal direction to press the repair tape from one end of the repair tape to the other end of the repair tape.
